(19) United States
(12) Patent Application Publication
(10) Pub. No.: US 2012/0025921 A1
(43) Pub. Date: Feb. 2, 2012

(54) Low Noise VCO Circuit Having Low Noise Bias

(75) Inventors: Yu Yang, Beijing (CN); Xuechu Li, Beijing (CN); Peiqi Xuan, Saratoga, CA (US)

(73) Assignee: QUINTIC HOLDINGS, Santa Clara, CA (US)

(21) Appl. No.: 12/893,280

(22) Filed: Sep. 29, 2010

Related U.S. Application Data
(60) Provisional application No. 61/369,683, filed on Jul. 31, 2010.

(51) Int. Cl. H03B 5/12

(52) U.S. Cl. 331/117 FE

(57) ABSTRACT

A low noise VCO circuit for an LC VCO circuit comprising MOS varactors is disclosed. The LC VCO circuit usually comprises an LC tuning circuit coupled with a pair of cross-coupled transistors used as a negative impedance element. A pair of varactors is used to provide fine tuning by applying a control voltage to the varactor. Since the varactor is also coupled to the pair of cross-coupled transistor, the process variation and temperature change may affect the bias voltage coupled to the pair of varactors. Therefore, a bias circuit usually is used to alleviate the impact of process variation and temperature change associated with the pair of transistor. Nevertheless, the bias voltage typically is implemented by providing a current flowing through a resistor, wherein the current is generated by a current source. The noise associated with the current source will affect the performance of the VCO circuit. A low noise VCO circuit is disclosed which utilizes a low noise bias circuit. The low noise bias circuit comprises a current source, a load device and a voltage divider wherein the load device is coupled to the voltage divider in parallel. The load device may be implemented using a bipolar transistor or a diode-connected MOS device.

### CROSS REFERENCE TO RELATED APPLICATIONS

The present invention claims priority to U.S. Provisional Patent Application, No. 61/369,683, filed Jul. 31, 2010, entitled “Low Noise VCO Circuit Having Low Noise Bias.” The U.S. Provisional patent application is hereby incorporated by reference in its entirety.

### FIELD OF THE INVENTION

The present invention relates to circuit for communication systems. In particular, the present invention relates to an LC VCO circuit having a low-noise bias circuit.

### BACKGROUND

In a radio receiver, a radio frequency (RF) signal is typically received using an antenna and the received RF is then processed along the receive path to recover the signal transmitted. In the receive path, the received signal is subject to various processing such as amplifying, filtering, down-converting, demodulating, and etc. The input signal usually covers a range of frequencies designated for a particular band. For example, for a terrestrial broadcast TV receiver, the tuning circuit has to support TV channels in the low VHF band (such as 44-92 MHz in the US), the high VHF band (such as 167-230 MHz in the US) and the UHF band (such as 470-860 MHz in the US). In a typical receiver, the input signal is converted to a signal at an intermediate frequency (IF), a low IF or a baseband frequency by mixing the input signal with a local oscillation (LO) signal. The LO frequency usually is derived from a frequency generated by voltage controlled oscillator (VCO). Accordingly, the VCO is required to provide a tuning range to accommodate the frequency range of the input signal. In the field of communication circuit, the VCO may also be abbreviation for voltage controlled oscillation. Therefore, the use of VCO for voltage controlled oscillation and voltage controlled oscillator is interchangeable.

In order to accommodate the tuning range, the VCO often utilizes an LC tuning circuit where a set of switched capacitor array (SCA) is used as a coarse adjustable capacitance device and a varactor is used as a fine adjustable capacitance device to provide continuous or fine adjustable tuning. The varactor used in the LC tuning circuit of the VCO usually provides a desired capacitance by applying a varactor control voltage, typically derived from a PLL loop filter, to a node of the varactor. If the difference between varactor body voltage and gate voltage is within a certain limit, the change in varactor capacitance is substantially proportional to the difference between varactor body voltage and varactor gate voltage. Often the drain and source of a MOS varactor is connected to the body of the MOS varactor so that a varactor is represented as a device having two nodes. The control voltage can be applied to the gate or the body of the MOS varactor and the bias voltage is applied to the other node. As to be discussed later, due to process variations and temperature change associated with cross-coupled transistors (for example, M3 and M4 in FIG. 1), the varactor gate to body voltage may fluctuate significantly if no DC blocking capacitors are incorporated to decouple the varactor from VCO output V_{O}+ and V_{O}−. In this case, the varactor may be unable to provide a desired capacitance value according to the linear model of capacitance versus voltage difference. Consequently, the VCO frequency may deviate from a desired frequency substantially and cause the PLL loop to become unstable. Since the VCO determines the LO phase noise, particularly at high frequency and the LO phase noise will degrade the SNR of received signal by a process known as reciprocal mixing, the quality of the bias will affect the system performance. Therefore, there is a need for a low noise and low variation bias. Since the VCO is also needed in a transmitter, the low noise VCO according to the present invention is also useful for the transmitter.

### BRIEF SUMMARY OF THE INVENTION

A low noise VCO circuit is disclosed. The low noise LC VCO comprises an LC resonant circuit comprising an inductive element and a pair of capacitive elements, a negative impedance element, and a DC bias circuit. The pair of capacitive elements has a capacitance value controlled by a control voltage. The negative impedance element comprising one or more cross-coupled transistor pairs, wherein each of said one or more cross-coupled transistor pairs comprises a first transistor and a second transistor, wherein first transistor gate is coupled to second transistor drain and second transistor gate is coupled to first transistor drain. The DC bias circuit provides a DC bias to the pair of capacitive elements, wherein the DC bias circuit comprises a current source, a load device and a voltage divider coupled to the load device in parallel. The DC bias is coupled to a middle contact of the voltage divider. The negative impedance element is coupled to the LC resonant circuit to cause the VCO circuit to oscillate at a frequency related to an inductance value of the inductive element and the capacitance value of the capacitive elements. In one embodiment, the load device is selected from a group consist of a PNP transistor, an NPN transistor, a diode-connected NMOS, and a diode-connected PMOS. The voltage divider comprises a first resistor and a second resistor connected in series, wherein a joint contact of the first resistor and the second resistor is coupled to the middle contact. The one or more cross-coupled transistor pairs is selected from a group consisting of a cross-coupled NMOS transistor pair, a cross-coupled PMOS transistor pair, and one cross-coupled NMOS transistor pair and one cross-coupled PMOS transistor pair.

### BRIEF DESCRIPTION OF THE DRAWINGS

FIG. 1A illustrates an exemplary LC VCO circuit with cross-coupled complementary transistors, where a DC bias is applied to the varactors.

FIG. 1B illustrates an exemplary LC VCO circuit with cross-coupled PMOS transistors, where a DC bias is applied to the varactors.

FIG. 2A illustrates an exemplary DC bias circuit using a current source and a resistor.

FIG. 2B illustrates an exemplary DC bias circuit using a current source and a transistor.

FIG. 3 illustrates an example of an embodiment of the low noise and low variation bias circuit.

FIG. 4A illustrates an example of an LC VCO circuit with cross-coupled complementary transistors using the DC bias circuit of FIG. 2A.

FIG. 4B illustrates an example of an LC VCO circuit with cross-coupled complementary transistors using the DC bias circuit of FIG. 2B.

FIG. 4C illustrates an example of an LC VCO circuit with cross-coupled complementary transistors using the low noise and low variation DC bias circuit of FIG. 3.

FIG. 4D illustrates an example of an LC VCO circuit with cross-coupled PMOS transistors using the low noise and low variation DC bias circuit of FIG. 3.

FIG. 5 shows a comparison of noise performance associated with the circuit of FIG. 2A and circuit of FIG. 3.

FIG. 6 demonstrates a comparison of temperature sensitivity associated with the circuit of FIG. 4B and circuit of FIG. 4C.

### DETAILED DESCRIPTION OF THE INVENTION

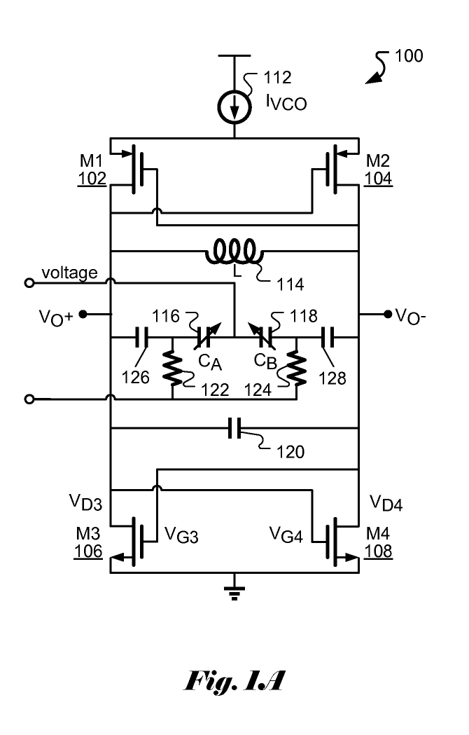

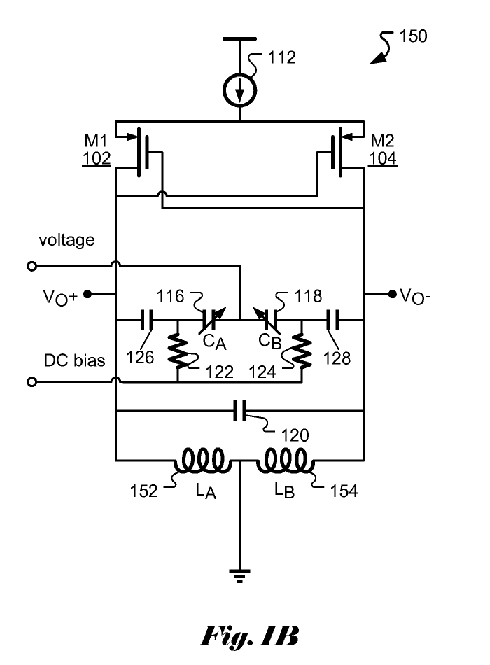

FIG. 1A illustrates an exemplary VCO circuit 100 incorporating an LC tuning circuit to adjust the frequency, wherein a pair of varactors C_{A} 116 and C_{B} 118 is used for fine frequency tuning. The LC tuning circuit comprises an inductor L 114, a fixed capacitor 120, and a pair of adjustable capacitors C_{A} 116 and C_{B} 118. The adjustable capacitors C_{A} 116 and C_{B} 118 are implemented using varactors. A DC bias is supplied to nodes of capacitors C_{A} 116 and C_{B} 118 through respective resistors 122 and 124 and the control voltage is applied to the common node of the two capacitors. Capacitors 126 and 128 serve as DC blocking capacitors to isolate the DC bias voltage from the output nodes V_{O}+ and V_{O}−. The VCO circuit uses cross-coupled transistors M3 106 and M4 108 as a negative impedance element to cause the LC tuning circuit to oscillate at a desired frequency. In order to increase the efficiency of the VCO circuit, a pair of cross-coupled complementary transistors M1 102 and M2 104 may also be included. Both transistors M3 106 and M4 108 are NMOS transistors while both transistors M1 102 and M2 104 are PMOS transistors. The current source I_{VCO} 112 is used to supply the needed current for the VCO circuit.

FIG. 1B illustrates another exemplary VCO implementation 150 where only PMOS transistors are used as the negative impedance element. The VCO circuit 150 is substantially the same as the VCO circuit 100 except that the NMOS transistor pair M3 106 and M4 108 is eliminated. Furthermore, the single inductor L 114 is replaced by a pair of inductors L_{A} 152 and L_{B} 154 with the common node connected to the ground. The VCO circuit in FIG. 1B has a lower cost compared with the VCO circuit in FIG. 1A due to the elimination of NMOS transistors M3 106 and M4 108. However, the efficiency of the VCO in FIG. 1B is less than that in FIG. 1A. Similarly, a VCO circuit may also be configured by eliminating the cross-coupled PMOS transistors of FIG. 1A and it will result in a VCO circuit having NMOS transistors only. The current invention is also applicable to VCO circuits having NMOS-only cross-coupled transistors.

One node of the MOS varactor usually is connected to a control voltage and the other node of the MOS varactor is connected to a bias voltage as shown in FIGS. 1A and 1B. The drain and source of the MOS varactor are connected together and are often further connected to the body of the MOS varactor. Therefore, the varactor is often considered as a two-node device. The control voltage can be applied to the node coupled to the gate. Nevertheless, the control voltage may also be connected to the node coupled to the body of the MOS varactor. The bias voltage is connected to the other node which is not coupled to the control voltage. There are also varactors configured to have the drain and source connected together which are separated from the body. In this case, drain-source connection is used as one of the MOS varactor nodes. The varactor DC bias noise will cause deviation of the varactor capacitance from a desired value. As a result, the LC resonance frequency will be changed. This change in the LC resonance frequency will be translated into VCO phase noise, called “narrow band frequency modulation”. Therefore the DC bias has to be low noise to ensure system performance.

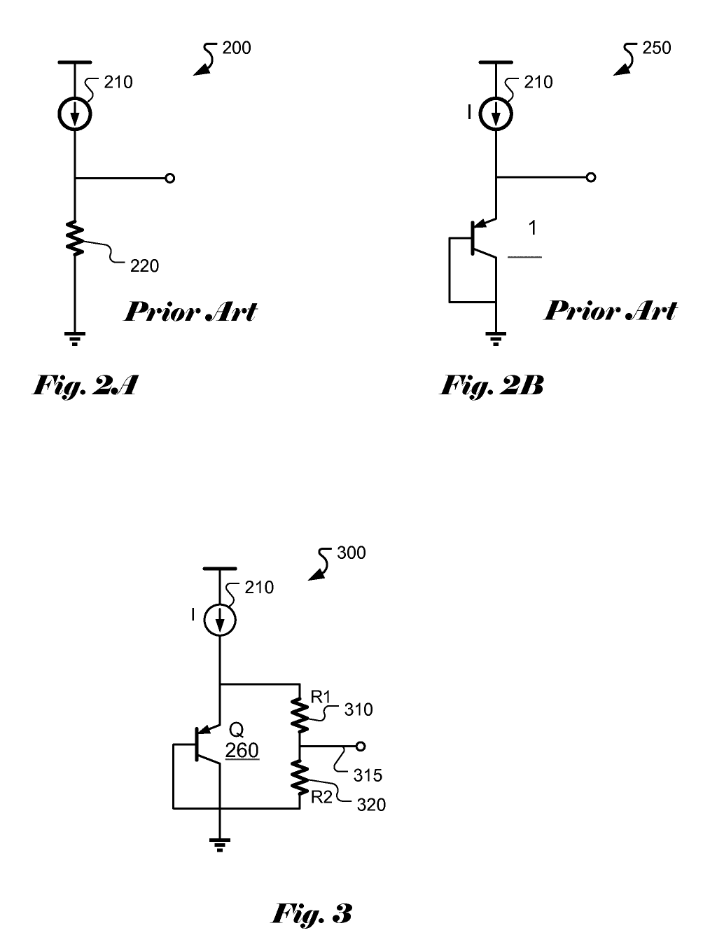

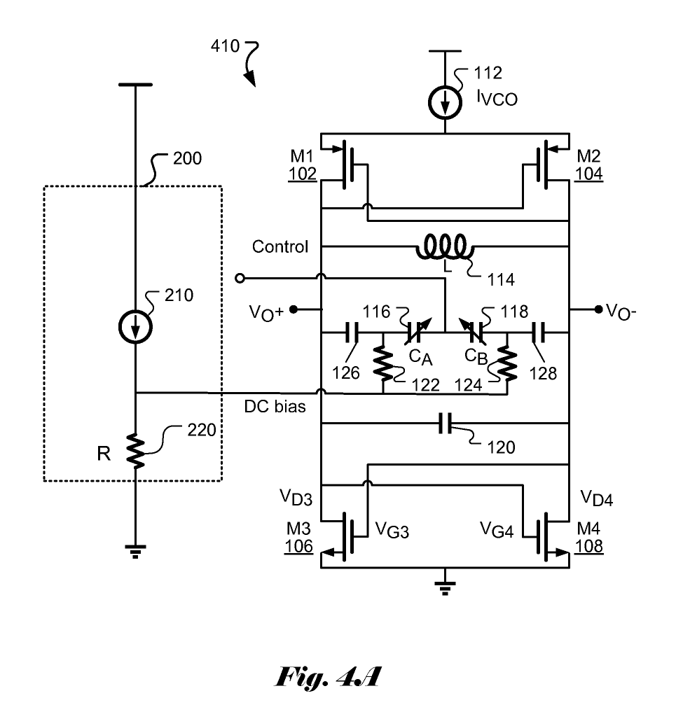

There are many possible ways to implement the bias circuit for the varactor. One implementation according to a prior art for providing the voltage bias, as shown in FIG. 2A, is to generate a bandgap current flowing through a resistor and the voltage drop across the resistor is used as the bias voltage. The bias circuit 200 comprises a current source I 210, which often utilizes a bandgap to generate the low-noise current and the current flows through resistor R 220 to provide the needed bias voltage. For high performance LC VCO, the bandgap current noise has to be very low. The low noise feature is achieved using a high current bandgap which leads to high power consumption and large silicon area. High power consumption is not favorable for portable applications and large silicon area implies high chip cost. Therefore, the bias circuit of FIG. 2A suffers the drawbacks of high power and large silicon area.

The bias noise can also be reduced by replacing the resistor of FIG. 2A with a transistor as shown in FIG. 2B, where a PNP transistor Q1 260 is used as a load to generate the bias voltage. While a PNP transistor Q1260 is used as a load in this example, it can be replaced with other impedance devices having small AC resistance, such as diode-connected NMOS, diode-connected PMOS, and NPN transistor. It is well known to these skilled in the art that the bias noise associated with FIG. 2B is much smaller than the bias noise associated with FIG. 2A. Nevertheless, the PNP transistor emitter voltage will change significantly with temperature. Furthermore, often there is a need for a voltage source follower circuit between the VCO control voltage and the PLL loop filter to reduce the leakage current or to shift the DC voltage. Also it is well known to these skilled in the art that the varactor DC bias variation and source follower variation will reduce the usable range of the VCO control voltage. Consequently it increases the VCO control voltage-to-frequency gain and increases the phase noise.

FIG. 3 illustrates an example of low noise and low variation DC bias circuit 300 according to one embodiment of the present invention, which comprises a current source I 210, a PNP transistor Q1 260 and a voltage divider. The voltage divider can be implemented by two resistors R1 310 and R2 320 as shown in FIG. 3. While resistors are used to form a voltage divider, other impedance elements may also be used to form the voltage divider. The PNP transistor Q1 260 is connected to the voltage divider in parallel. The current source flows through the emitter of the PNP transistor Q1 260 and the voltage divider. The low noise and low variation DC bias is coupled to the middle contact 315 of the voltage divider as shown in FIG. 3.

In FIG. 3, the PNP transistor Q1 260 is usually based on the substrate bipolar transistor, where the collector of such transistors is formed by the substrate and is thus grounded. The collector current, k, can be derived as in eqn. (1):

$$Ic = Is * exp ( \frac{{V}_{BE}}{kT / q} ) , \qquad ( 1 )$$

where k is Boltzmann's constant, q is the electron charge, T is the absolute temperature, V_{BE} is the base-emitter voltage, and Is is the transistor's saturation current. The small signal resistance seen from the emitter of the PNP transistor Q1 260 transistor is shown in eqn. (2):

$$Rin = \frac{kT / q}{Ic} . \qquad ( 2 )$$

At 20° C., kT/q is about 26 mV.

The current noise, In, of the current source is mainly contributed by the bandgap used in the current source. In order to reduce the current noise, high power consumption and large silicon area have to be used to implement the bandgap. Otherwise, the current noise will be high. The noise voltage of the emitter of the PNP transistor Q1 260 can be derived according to eqn. (3):

Vn=In*(Rin//(R1+R2)) (3)

For example, if I=100 μA, R1=10 kΩ, R2=5 kΩ and the base-to-emitter voltage V_{BE} of the PNP transistor Q1 260 is about 0.75V, the bias output will be 0.75/3V, i.e., 0.25V. Then the current flowing through the emitter of the PNP transistor Q1 260 is about 50 μA. The noise voltage Vn and the noise voltage for the bias Vn bias can be derived according to eqn. (4) and eqn. (5) respectively:

$$\begin{matrix}\begin{matrix}Vn = In * ( Rin // ( R 1 + R 2 ) ) \\ = In * ( \frac{26 mV}{50 uA} // 15 K ) \\ \approx In * 500 Ω ,\end{matrix} \\ and & ( 4 ) \\ \begin{matrix}Vn\_bias \approx 1 / 3 * In * ( Rin // ( R 1 + R 2 ) ) \\ \approx In * \frac{500}{3} Ω .\end{matrix} & ( 5 )\end{matrix}$$

On the other hand, the noise voltage of the prior art DC bias in FIG. 2A is equal to In *R. For 100 μA current and 0.25V output voltage, R is about 2.5 ka The new bias circuit of FIG. 3 by incorporating a voltage divider comprising resistors R1 310 and R2 320 coupled to the PNP transistor Q1 260 in parallel can significantly reduce the noise voltage.

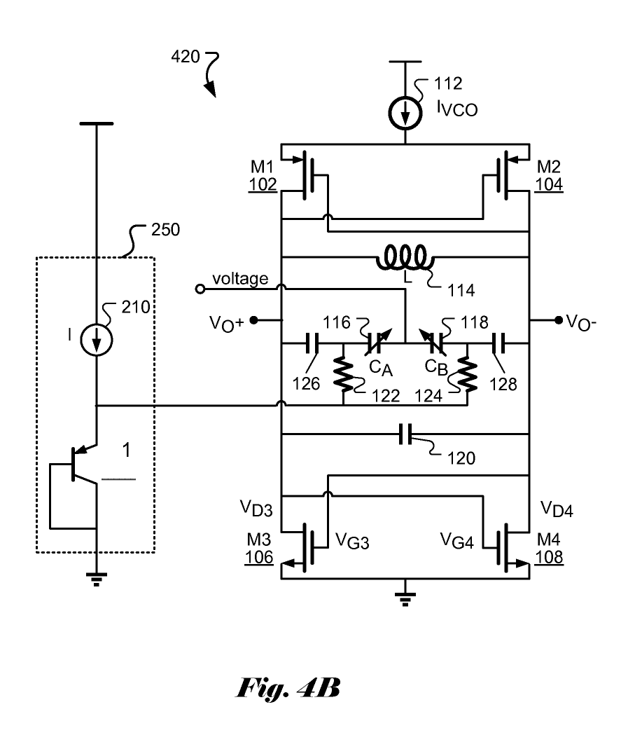

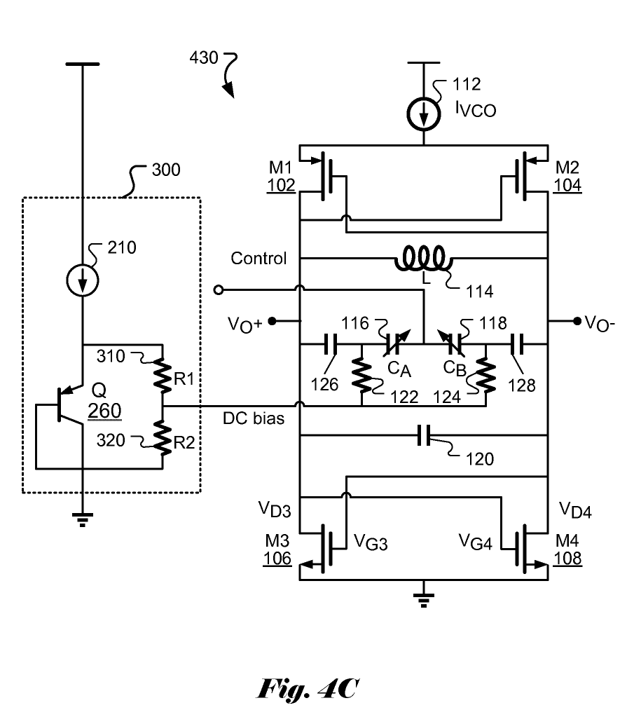

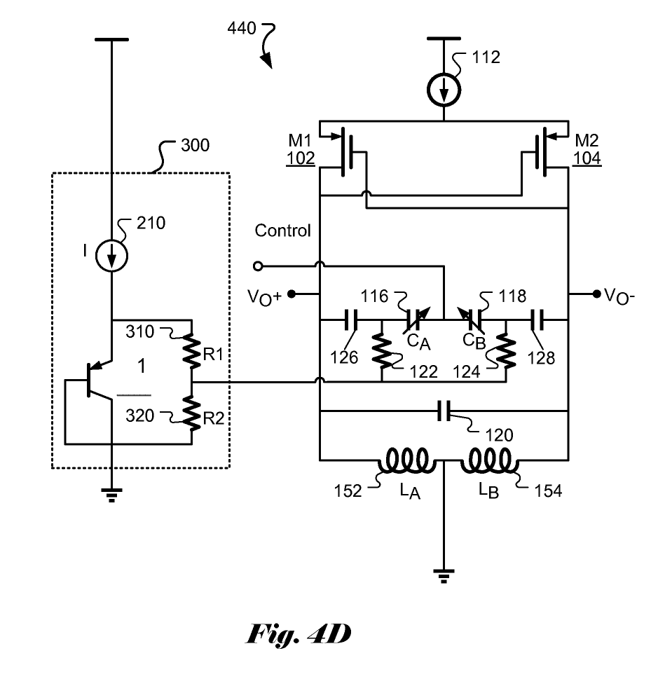

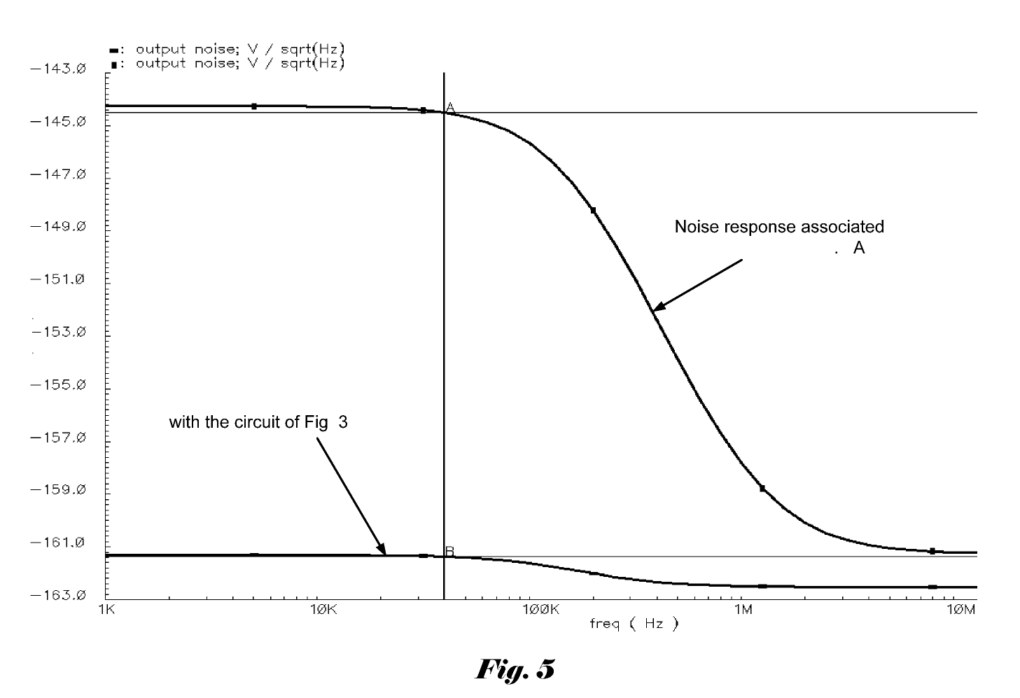

FIG. 4A illustrates an example of an LC VCO circuit 410 with cross-coupled complementary transistors using the DC bias circuit of FIG. 2A. FIG. 4B illustrates an example of an LC VCO circuit 420 with cross-coupled complementary transistors using the DC bias circuit of FIG. 2B. FIG. 4C illustrates an example of an LC VCO circuit 430 with cross-coupled complementary transistors using the low noise and low variation DC bias circuit of FIG. 3. FIG. 4D illustrates an example of an LC VCO circuit 440 with cross-coupled PMOS-only transistors using the low noise and low variation DC bias circuit of FIG. 3.

FIG. 5 demonstrates a comparison of noise performance associated with the circuit of FIG. 2A and circuit of FIG. 3. As shown in FIG. 5, the total noise of the low noise bias of FIG. 3 is about 17 db lower than that using a prior art DC bias.

The base-emitter voltage of a bipolar transistor exhibits a negative temperature constant according to Behzad Razavi, Design of Analog CMOS Integrated Circuits, New York: McGraw-Hill, 2001, pp 389, is shown in eqn. (6):

$$\frac{\partial {V}_{BE}}{\partial T} = \frac{{V}_{BE} - ( 4 + m ) VT - Eg / q}{T} , \qquad ( 6 )$$

where m is about −3/2, and Eg≈1.12 eV is the bandgap energy of silicon. With V_{BE}≈0.75V and T=300° K.,

$$\frac{\partial {V}_{BE}}{\partial T}$$

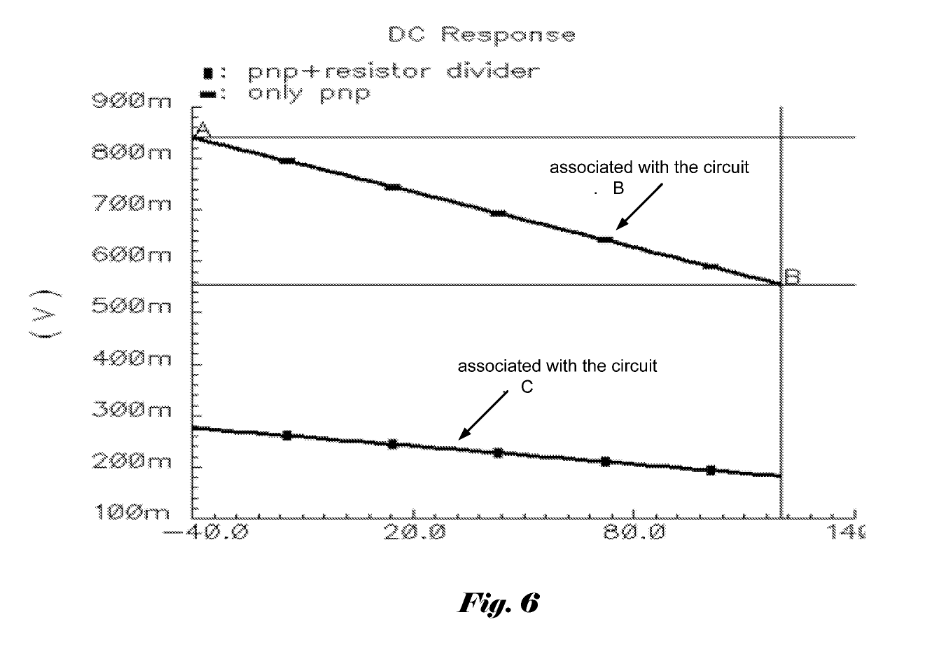

is approximately −1.5 mV/K. Simulation results show that the variation is about 0.285V for temperature varying from −40° C. to 120° C. For the VCO circuit using the low noise and low variation bias disclosed herein, the variation of the PNP transistor emitter voltage with temperature is also divided due to the voltage divider. Consequently, the variation in the low noise bias output is only ⅓ of the PNP transistor emitter voltage. FIG. 6 demonstrates a comparison of temperature sensitivity associated with the circuit of FIG. 4B and the circuit of FIG. 4C. Because of the small AC resistance seen at the emitter of the PNP transistor Q1 260 and the resistor voltage divider, the Power Supply Rejection Ratio (PSRR) of the low noise and low variation bias is very good.

The invention may be embodied in other specific forms without departing from its spirit or essential characteristics. The described examples are to be considered in all respects only as illustrative and not restrictive. The scope of the invention is, therefore, indicated by the appended claims rather than by the foregoing description. All changes which come within the meaning and range of equivalency of the claims are to be embraced within their scope.

1. A low-noise voltage controlled oscillation (VCO) circuit comprising:
an LC resonant circuit comprising an inductive element and a pair of capacitive elements, wherein the pair of capacitive elements has a capacitance value controlled by a control voltage;
a negative impedance element comprising one or more cross-coupled transistor pairs, wherein each of said one or more cross-coupled transistor pairs comprises a first transistor and a second transistor, wherein first transistor gate is coupled to second transistor drain and second transistor gate is coupled to first transistor drain;
a DC bias circuit to provide a DC bias to the pair of capacitive elements, wherein the DC bias circuit comprises a current source, a load device and a voltage divider coupled to the load device in parallel, and wherein the DC bias is coupled to a middle contact of the voltage divider; and
wherein the negative impedance element is coupled to the LC resonant circuit to cause the VCO circuit to oscillate at a frequency related to an inductance value of the inductive element and the capacitance value of the capacitive elements.

2. The circuit of claim 1, wherein the load device is selected from a group consist of a PNP transistor, an NPN transistor, a diode-connected NMOS, and a diode-connected PMOS.

3. The circuit of claim 1, wherein the voltage divider comprises a first resistor and a second resistor connected in series, wherein a joint contact of the first resistor and the second resistor is coupled to the middle contact.

4. The circuit of claim 1, wherein the inductive element is an inductor.

5. The circuit of claim 1, wherein said one or more cross-coupled transistor pairs is a cross-coupled NMOS transistor pair.

6. The circuit of claim 1, wherein said one or more cross-coupled transistor pairs is a cross-coupled PMOS transistor pair.

7. The circuit of claim 1, wherein said one or more cross-coupled transistor pairs comprises one cross-coupled NMOS transistor pair and one cross-coupled PMOS transistor pair.
